(19) United States
(12) Patent Application Publication
(10) Pub. No.: US 2023/0345769 A1
(43) Pub. Date: Oct. 26, 2023

(54) DISPLAY DEVICE AND MANUFACTURING METHOD THEREOF

(71) Applicant: Japan Display Inc., Tokyo (JP)

(72) Inventor: Arichika ISHIDA, Tokyo (JP)

(73) Assignee: Japan Display Inc., Tokyo (JP)

(21) Appl. No.: 18/299,078

(22) Filed: Apr. 12, 2023

(30) Foreign Application Priority Data
Apr. 22, 2022 (JP) 2022-070757

(51) Int. Cl. H10K 59/122; H10K 59/80; H10K 59/12

(52) U.S. Cl. CPC H10K 59/122; H10K 59/80515; H10K 59/1201

(57) ABSTRACT

According to one embodiment, a display device includes a lower electrode, a rib covering a part of the lower electrode and includes a pixel aperture overlapping the lower electrode, an upper electrode facing the lower electrode, and an organic layer between the lower and upper electrodes. The lower electrode includes a metal layer including a first peripheral portion covered with the rib, and a first central portion exposed from the rib through the pixel aperture, and a conductive oxide layer including a second peripheral portion located on the rib, and a second central portion which is in contact with the first central portion through the pixel aperture.

### CROSS-REFERENCE TO RELATED APPLICATIONS

This application is based upon and claims the benefit of priority from Japanese Patent Application No. 2022-070757, filed Apr. 22, 2022, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

When such a display device is manufactured, a technique which prevents the reduction in reliability is required.

### BRIEF DESCRIPTION OF THE DRAWINGS

FIG. 1 is a diagram showing a configuration example of a display device according to an embodiment.

FIG. 2 is a diagram showing an example of the layout of subpixels.

FIG. 3 is a schematic cross-sectional view of the display device along the III-III line of FIG. 2.

FIG. 4 is a schematic cross-sectional view of a partition and its vicinity according to the embodiment.

FIG. 5 is a schematic plan view of lower electrodes and protective layers according to the embodiment.

FIG. 6 is a schematic cross-sectional view showing part of the manufacturing process of the display device according to the embodiment.

FIG. 7 is a schematic cross-sectional view showing a process following FIG. 6.

FIG. 8 is a schematic cross-sectional view showing a process following FIG. 7.

FIG. 9 is a schematic cross-sectional view showing a process following FIG. 8.

FIG. 10 is a schematic cross-sectional view showing a process following FIG. 9.

FIG. 11 is a schematic cross-sectional view showing a process following FIG. 10.

FIG. 12 is a schematic cross-sectional view showing a process following FIG. 11.

FIG. 13 is a schematic cross-sectional view showing a process following FIG. 12.

FIG. 14 is a schematic cross-sectional view showing a process following FIG. 13.

FIG. 15 is a schematic cross-sectional view showing a process following FIG. 14.

### DETAILED DESCRIPTION

In general, according to one embodiment, a display device comprises a lower electrode, a rib which covers a part of the lower electrode and comprises a pixel aperture overlapping the lower electrode, an upper electrode which faces the lower electrode, and an organic layer which is provided between the lower electrode and the upper electrode and emits light based on a potential difference between the lower electrode and the upper electrode. The lower electrode includes a metal layer comprising a first peripheral portion covered with the rib, and a first central portion exposed from the rib through the pixel aperture, and a conductive oxide layer comprising a second peripheral portion located on the rib, and a second central portion which is in contact with the first central portion through the pixel aperture.

According to another embodiment, a display device comprises a lower electrode, a rib which covers a part of the lower electrode and comprises a pixel aperture overlapping the lower electrode, an upper electrode which faces the lower electrode, an organic layer which is provided between the lower electrode and the upper electrode and emits light based on a potential difference between the lower electrode and the upper electrode, and a protective layer located between the lower electrode and the rib. The lower electrode includes a metal layer comprising a first peripheral portion covered with the rib, and a first central portion exposed from the rib through the pixel aperture, and a conductive oxide layer which covers the first central portion. The protective layer covers the first peripheral portion.

According to yet another embodiment, a manufacturing method of a display device includes forming a metal layer, forming a protective layer which covers the metal layer, forming a rib which covers a part of the protective layer and comprises a pixel aperture overlapping the protective layer, removing, of the protective layer, a portion exposed from the rib through the pixel aperture such that a first central portion of the metal layer is exposed from the protective layer, forming a conductive oxide layer which is in contact with the first central portion through the pixel aperture, forming an organic layer which covers the conductive oxide layer, and forming an upper electrode which covers the organic layer.

The embodiments can provide a display device in which the reliability can be improved and a manufacturing method thereof.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When this specification uses terms indicating the positional relationships of two or more elements, such as “on”, “above” and “face” in phrases “an element is provided on another element”, “an element is provided above another element” and “an element faces another element”, the two or more elements may be directly in contact with each other, or a gap or another element may be interposed between the elements.

The display device of the present embodiment is an organic electroluminescent (EL) display device comprising an organic light emitting diode (OLED) as a display element, and could be mounted on a television, a personal computer, a vehicle-mounted device, a tablet, a smartphone, a mobile phone, etc.

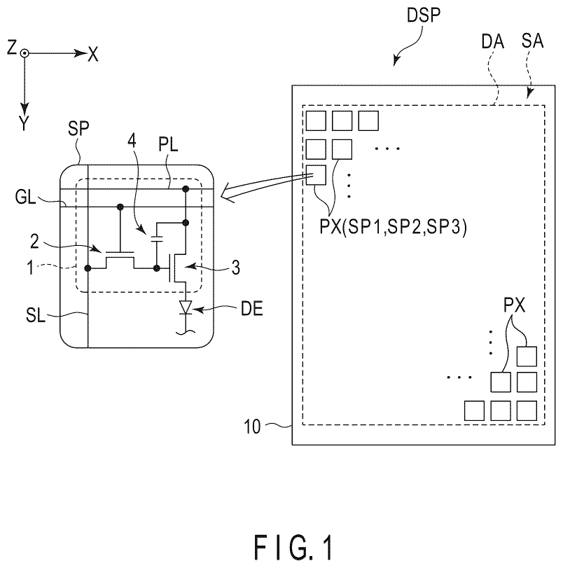

FIG. 1 is a diagram showing a configuration example of a display device DSP according to an embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a red first subpixel SP1, a green second subpixel SP2 and a blue third subpixel SP3. Each pixel PX may include a subpixel SP which exhibits another color such as white in addition to subpixels SP1, SP2 and SP3 or instead of one of subpixels SP1, SP2 and SP3. The number of subpixels SP constituting each pixel PX may be less than or equal to two.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE. The display element DE is an organic light emitting diode (OLED) as a light emitting element.

It should be noted that the configuration of the pixel circuit 1 is not limited to the example shown in the figure. For example, the pixel circuit 1 may comprise more thin-film transistors and capacitors.

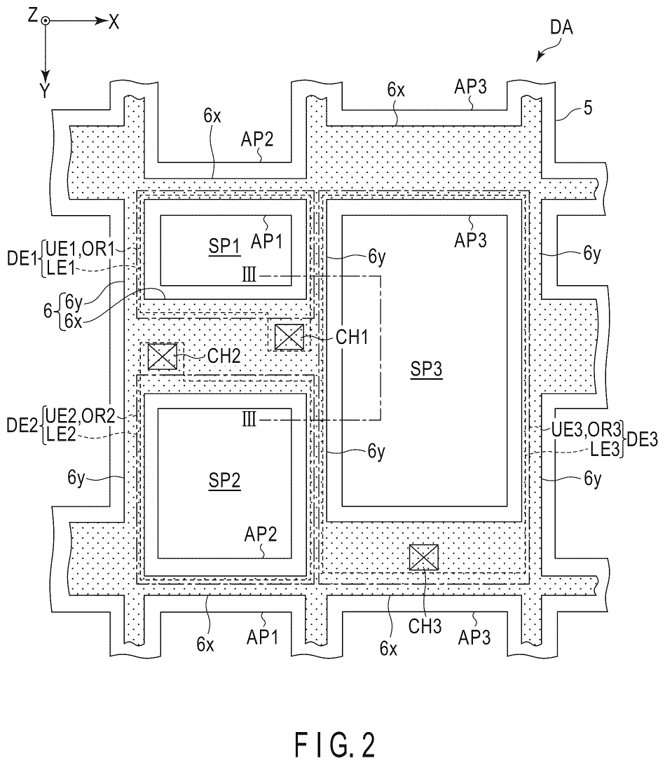

FIG. 2 is a diagram showing an example of the layout of subpixels SP1, SP2 and SP3. In the example of FIG. 2, the first subpixel SP1 and the third subpixel SP3 are arranged in the first direction X. The second subpixel SP2 and the third subpixel SP3 are also arranged in the first direction X. Further, the first subpixel SP1 and the second subpixel SP2 are arranged in the second direction Y.

When subpixels SP1, SP2 and SP3 are provided in line with this layout, in the display area DA, a column in which subpixels SP1 and SP2 are alternately provided in the second direction Y and a column in which a plurality of third subpixels SP3 are repeatedly provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises a first pixel aperture AP1 in the first subpixel SP1, comprises a second pixel aperture AP2 in the second subpixel SP2 and comprises a third pixel aperture AP3 in the third subpixel SP3. In the example of FIG. 2, the second pixel aperture AP2 is larger than the first pixel aperture AP1, and the third pixel aperture AP3 is larger than the second pixel aperture AP2.

The partition 6 is provided in the boundary between adjacent subpixels SP and overlaps the rib 5 as seen in plan view. The partition 6 comprises a plurality of first partitions 6x extending in the first direction X and a plurality of second partitions 6y extending in the second direction Y. The first partitions 6x are provided between the pixel apertures AP1 and AP2 which are adjacent to each other in the second direction Y and between two third pixel apertures AP3 which are adjacent to each other in the second direction Y. Each second partition 6y is provided between the pixel apertures AP1 and AP3 which are adjacent to each other in the first direction X and between the pixel apertures AP2 and AP3 which are adjacent to each other in the first direction X.

In the example of FIG. 2, the first partitions 6x and the second partitions 6y are connected to each other. In this configuration, the partition 6 has a grating shape surrounding the pixel apertures AP1, AP2 and AP3 as a whole. In other words, the partition 6 comprises apertures in subpixels SP1, SP2 and SP3 in a manner similar to that of the rib 5.

The first subpixel SP1 comprises a first lower electrode LE1, a first upper electrode UE1 and a first organic layer OR1 overlapping the first pixel aperture AP1. The second subpixel SP2 comprises a second lower electrode LE2, a second upper electrode UE2 and a second organic layer OR2 overlapping the second pixel aperture AP2. The third subpixel SP3 comprises a third lower electrode LE3, a third upper electrode UE3 and a third organic layer OR3 overlapping the third pixel aperture AP3.

The first lower electrode LE1, the first upper electrode UE1 and the first organic layer OR1 constitute the first display element DE1 of the first subpixel SP1. The second lower electrode LE2, the second upper electrode UE2 and the second organic layer OR2 constitute the second display element DE2 of the second subpixel SP2. The third lower electrode LE3, the third upper electrode UE3 and the third organic layer OR3 constitute the third display element DE3 of the third subpixel SP3. Each of the display elements DE1, DE2 and DE3 may include a cap layer as described later.

The first lower electrode LE1 is connected to the pixel circuit 1 (see FIG. 1) of the first subpixel SP1 through a first contact hole CH1. The second lower electrode LE2 is connected to the pixel circuit 1 of the second subpixel SP2 through a second contact hole CH2. The third lower electrode LE3 is connected to the pixel circuit 1 of the third subpixel SP3 through a third contact hole CH3.

In the example of FIG. 2, the contact holes CH1 and CH2 entirely overlap the first partition 6X between the pixel apertures AP1 and AP2 which are adjacent to each other in the second direction Y. The third contact hole CH3 entirely overlaps the first partition 6x between two third pixel apertures AP3 which are adjacent to each other in the second direction Y. As another example, at least part of the contact hole CH1, CH2 or CH3 may not overlap the first partition 6x.

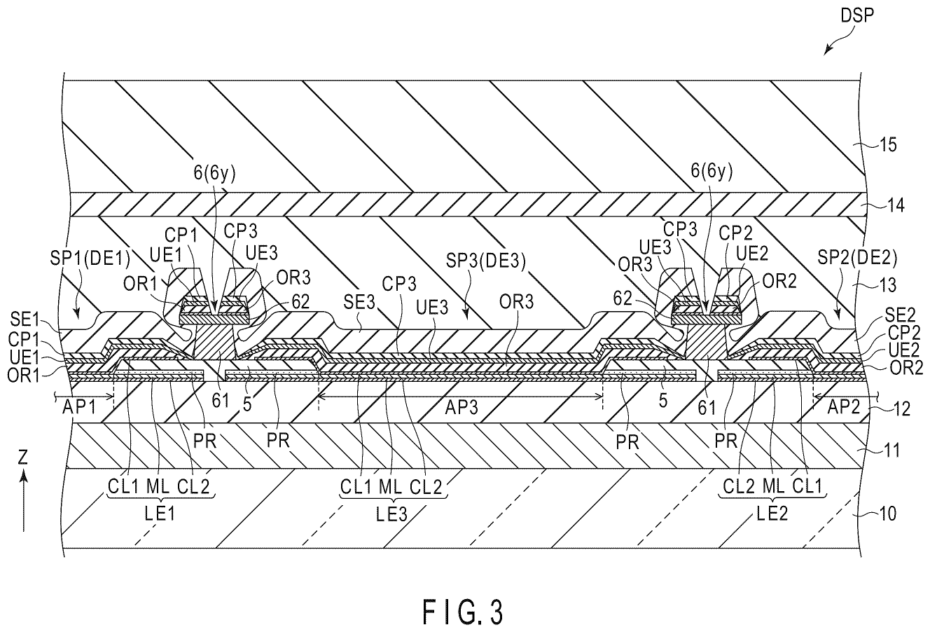

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an organic insulating layer 12. The organic insulating layer 12 functions as a planarization film which planarizes the irregularities formed by the circuit layer 11. Although not shown in the section of FIG. 3, all of the contact holes CH1, CH2 and CH3 described above are provided in the organic insulating layer 12.

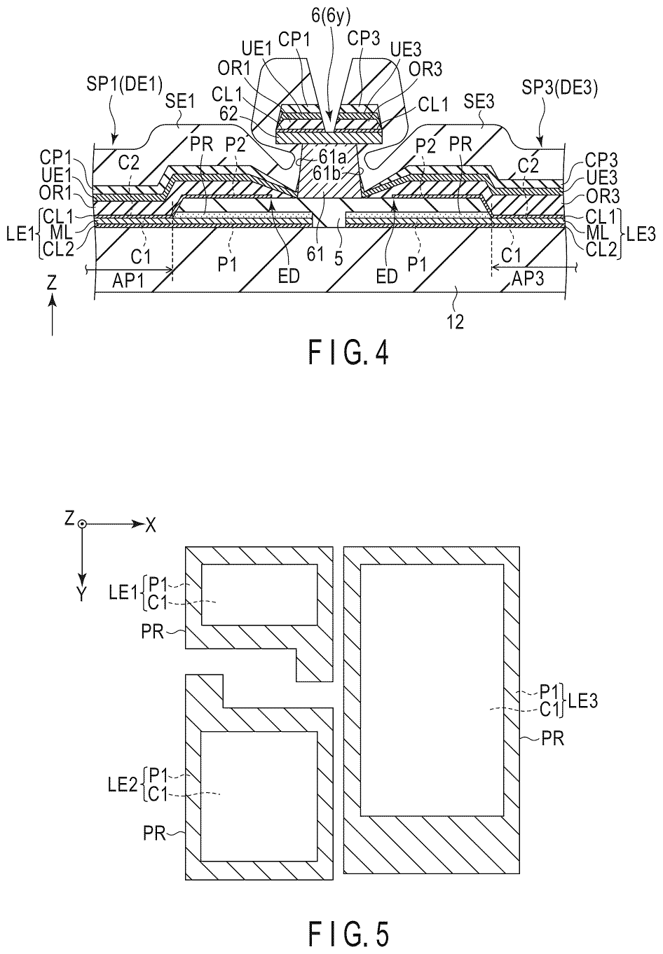

The lower electrodes LE1, LE2 and LE3 are provided on the organic insulating layer 12. As explained in detail later with reference to FIG. 4, in the present embodiment, each of the lower electrodes LE1, LE2 and LE3 includes a metal layer ML, a first conductive oxide layer CL1 and a second conductive oxide layer CL2.

The rib 5 is provided on the organic insulating layer 12 and the lower electrodes LE1, LE2 and LE3 and comprises the pixel apertures AP1, AP2 and AP3 described above. The lower electrodes LE1, LE2 and LE3 are partly covered with the rib 5. In a third direction Z, a protective layer PR is provided between each of the lower electrodes LE1, LE2 and LE3 and the rib 5.

The partition 6 includes a conductive lower portion 61 provided on the rib 5 and an upper portion 62 provided on the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 is called an overhang shape.

The first organic layer OR1 covers the first lower electrode LE1. The first upper electrode UE1 covers the first organic layer OR1 and faces the first lower electrode LE1. The second organic layer OR2 covers the second lower electrode LE2. The second upper electrode UE2 covers the second organic layer OR2 and faces the second lower electrode LE2. The third organic layer OR3 covers the third lower electrode LE3. The third upper electrode UE3 covers the third organic layer OR3 and faces the third lower electrode LE3.

In the example of FIG. 3, a first cap layer CP1 is provided on the first upper electrode UE1. A second cap layer CP2 is provided on the second upper electrode UE2. A third cap layer CP3 is provided on the third upper electrode UE3. The cap layers CP1, CP2 and CP3 adjust the optical property of the light emitted from the organic layers OR1, OR2 and OR3, respectively.

The first organic layer OR1, the first upper electrode UE1 and the first cap layer CP1 are partly located on the upper portion 62. These portions are spaced apart from the other portions of the first organic layer OR1, the first upper electrode UE1 and the first cap layer CP1. Similarly, the second organic layer OR2, the second upper electrode UE2 and the second cap layer CP2 are partly located on the second portion 62, and these portions are spaced apart from the other portions of the second organic layer OR2, the second upper electrode UE2 and the second cap layer CP2. Further, the third organic layer OR3, the third upper electrode UE3 and the third cap layer CP3 are partly located on the upper portion 62, and these portions are spaced apart from the other portions of the third organic layer OR3, the third upper electrode UE3 and the third cap layer CP3.

A first sealing layer SE1 is provided in the first subpixel SP1. A second sealing layer SE2 is provided in the second subpixel SP2. A third sealing layer SE3 is provided in the third subpixel SP3. The first sealing layer SE1 continuously covers the first cap layer CP1 and the partition 6 around the first subpixel SP1. The second sealing layer SE2 continuously covers the second cap layer CP2 and the partition 6 around the second subpixel SP2. The third sealing layer SE3 continuously covers the third cap layer CP3 and the partition 6 around the third subpixel SP3.

The end portions (peripheral portions) of the sealing layers SE1, SE2 and SE3 are located above the upper portions 62. In the example of FIG. 3, the end portions of the sealing layers SE1 and SE3 located above the upper portion 62 of the partition 6 between subpixels SP1 and SP3 are spaced apart from each other. The end portions of the sealing layers SE2 and SE3 located above the upper portion 62 of the partition 6 between subpixels SP2 and SP3 are spaced apart from each other.

The sealing layers SE1, SE2 and SE3 are covered with a resin layer 13. The resin layer 13 is covered with a sealing layer 14. Further, the sealing layer 14 is covered with a resin layer 15.

The organic insulating layer 12 and the resin layers 13 and 15 are formed of an organic material. The rib 5 and the sealing layers 14, SE1, SE2 and SE3 are formed of, for example, an inorganic material such as silicon nitride (SiN), silicon oxide (SiO) or silicon oxynitride (SiON).

The upper electrodes UE1, UE2 and UE3 are formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

Each of the organic layers OR1, OR2 and OR3 includes a plurality of functional layers and a light emitting layer. For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. It should be noted that the configuration of the organic layer OR1, OR2 or OR3 is not limited to this example. One of the functional layers described above may be omitted. Another functional layer may be added.

The cap layers CP1, CP2 and CP3 are formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that at least one of the cap layers CP1, CP2 and CP3 may be omitted.

The lower portion 61 of the partition 6 is formed of, for example, aluminum (Al). The lower portion 61 may be formed of an aluminum alloy such as an aluminum-neodymium alloy (AlNd) or may comprise a multilayer structure consisting of an aluminum layer and an aluminum alloy layer. Further, the lower portion 61 may comprise a thin film formed of a metal material different from aluminum and an aluminum alloy under the aluminum layer or the aluminum alloy layer. This thin film can be formed of, for example, molybdenum (Mo).

For example, the upper portion 62 of the partition 6 comprises a multilayer structure consisting of a first thin film formed of a metal material such as titanium (Ti) and a second thin film formed of a transparent conductive oxide. For the conductive oxide forming the second thin film, for example, indium tin oxide (ITO), indium zinc oxide (IZO) or indium gallium zinc oxide (IGZO) may be used. The upper portion 62 may comprise a single-layer structure of a metal material such as titanium. The upper portion 62 may comprise a single-layer structure of an inorganic material such as silicon oxide.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the first lower electrode LE1 and the first upper electrode UE1, the light emitting layer of the first organic layer OR1 emits light in a red wavelength range. When a potential difference is formed between the second lower electrode LE2 and the second upper electrode UE2, the light emitting layer of the second organic layer OR2 emits light in a green wavelength range. When a potential difference is formed between the third lower electrode LE3 and the third upper electrode UE3, the light emitting layer of the third organic layer OR3 emits light in a blue wavelength range.

FIG. 4 is a schematic cross-sectional view in which the partition 6 provided between subpixels SP1 and SP3 and its vicinity are enlarged. In this figure, the substrate 10, the circuit layer 11, the resin layer 13, the sealing layer 14 and the resin layer 15 are omitted.

The lower portion 61 of the partition 6 comprises a pair of side surfaces 61a and 61b. The both end portions of the upper portion 62 protrude relative to the side surfaces 61a and 61b. In the example of FIG. 4, the lower portion 61 is shaped so as to taper toward the upper portion 62. In other words, the side surfaces 61a and 61b incline with respect to the third direction Z such that the distance between them is decreased toward the upper portion 62. As another example, the side surfaces 61a and 61b may be substantially parallel to the third direction Z.

The first lower electrode LE1 comprises the metal layer ML, the first conductive oxide layer CL1 and the second conductive oxide layer CL2. The second conductive oxide layer CL2 is provided on the organic insulating layer 12.

The metal layer ML is provided on the second conductive oxide layer CL2. The metal layer ML comprises a first peripheral portion P1 covered with the rib 5, and a first central portion C1 exposed from the rib 5 through the first pixel aperture AP1.

The first conductive oxide layer CL1 comprises a second peripheral portion P2 located on the rib 5, and a second central portion C2 which is in contact with the first central portion C1 through the first pixel aperture AP1. The second peripheral portion P2 and the second central portion C2 are covered with the first organic layer OR1.

An end portion ED of the second peripheral portion P2 is covered with the first organic layer OR1 and is spaced apart from the lower portion 61 and the first upper electrode UE1. The first upper electrode UE1 is in contact with the side surface 61a of the lower portion 61.

The first peripheral portion P1 is covered with the protective layer PR. The protective layer PR is covered with the rib 5 together with the first peripheral portion P1. In the example of FIG. 4, the first peripheral portion P1 is entirely covered with the protective layer PR. However, the first peripheral portion P1 may be partly exposed from the protective layer PR.

The metal layer ML is formed of, for example, silver (Ag), and reflects the light emitted from the first organic layer OR1 to the upper side. The conductive oxide layers CL1 and CL2 are formed of, for example, ITO, and prevent the oxidation of the metal layer ML. Further, the first conductive oxide layer CL1 improves the work function of the first lower electrode LE1. The second conductive oxide layer CL2 improves the adherence of the first lower electrode LE1 and the organic insulating layer 12. The conductive oxide layers CL1 and CL2 may be formed of, for example, a transparent conductive oxide other than ITO, such as IZO and IGZO.

The protective layer PR is formed of, for example, a conductive material such as ITO so as to be thicker than the first conductive oxide CL1. The protective layer PR may be formed of, for example, a conductive oxide other than ITO, such as IZO and IGZO. The protective layer PR may be formed of an insulating material.

The structures of the second lower electrode LE2 and the third lower electrode LE3 are similar to the structure of the first lower electrode LE1. In other words, each of the lower electrodes LE2 and LE3 comprises the metal layer ML, the first conductive oxide layer CL1 and the second conductive oxide layer CL2. Further, the metal layer ML of each of the lower electrodes LE2 and LE3 comprises the first peripheral portion P1 and the first central portion C1. The first conductive oxide layer CL1 of each of the lower electrodes LE2 and LE3 comprises the second peripheral portion P2 and the second central portion C2. The first peripheral portion P1 of the metal layer ML of each of the lower electrodes LE2 and LE3 is covered with the protective layer PR.

In the example of FIG. 4, a pair of first conductive oxide layers CL1 is also attached to the upper side of the upper portion 62 of the partition 6. These first conductive oxide layers CL1 are covered with the organic layers OR1 and OR3 located on the upper portion 62, respectively. It should be noted that these first conductive oxide layers CL1 may be spaced apart from each other as shown in the figure or may be continuous with each other.

FIG. 5 is a schematic plan view of the lower electrodes LE1, LE2 and LE3 and the protective layers PR. The three frame-like portions indicated by diagonal lines correspond to the first peripheral portions P1 of the lower electrodes LE1, LE2 and LE3. Further, the inner portions of the first peripheral portions P1 correspond to the first central portions C1 of the lower electrodes LE1, LE2 and LE3.

In the example of FIG. 5, for the first peripheral portion P1 of each of the lower electrodes LE1, LE2 and LE3, the protective layer PR having the same shape as the first peripheral portion P1 is provided. In other words, in each of the lower electrodes LE1, LE2 and LE3, the protective layer PR and the first peripheral portion P1 surround the first central portion C1.

Now, this specification explains the manufacturing method of the display device DSP.

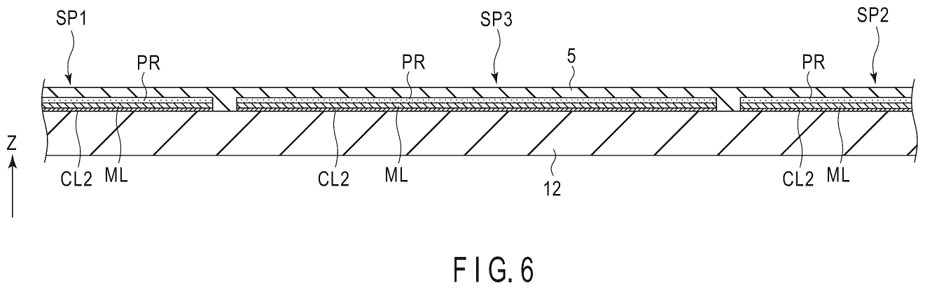

FIG. 6 to FIG. 15 are schematic cross-sectional views showing part of the manufacturing process of the display device DSP in the present embodiment. In these figures, the substrate 10 and the circuit layer 11 are omitted.

To manufacture the display device DSP, first, the circuit layer 11 and the organic insulating layer 12 are formed on the substrate 10 shown in FIG. 3. Subsequently, as shown in FIG. 6, the second conductive oxide layer CL2 is formed on the organic insulating layer 12 for each of subpixels SP1, SP2 and SP3. The metal layers ML are formed so as to entirely cover the second conductive oxide layers CL2. The protective layers PR are formed so as to entirely cover the metal layers ML. Further, the rib 5 (in other words, an insulating layer which is the base of the rib 5) is formed. At this point, the rib 5 does not comprise the pixel aperture AP1, AP2 or AP3 and entirely covers the second conductive oxide layers CL2, the metal layers ML and the protective layers PR.

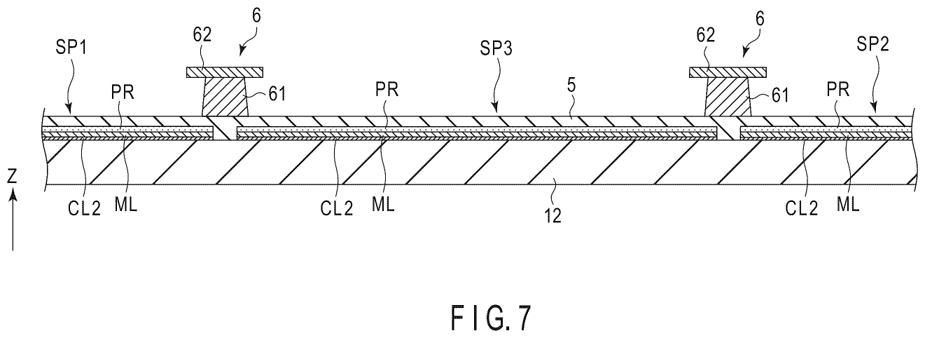

Subsequently, as shown in FIG. 7, the partition 6 is formed on the rib 5. Regarding the formation of the partition 6, first, a first layer which is the base of the lower portion 61 is formed. A second layer which is the base of the upper portion 62 is formed on the first layer. A resist having the planar shape of the partition 6 is provided on the second layer. Further, the first layer and the second layer are patterned by anisotropic dry etching. By this process, the lower portion 61 and the upper portion 62 are formed. Subsequently, the width of the lower portion 61 is reduced relative to the upper portion 62 by isotropic wet etching.

After the formation of the partition 6, a process for forming the display elements DE1, DE2 and DE3 is performed. In the present embodiment, for example, this specification assumes a case where the third display element DE3 is formed firstly, and the second display element DE2 is formed secondly, and the first display element DE1 is formed lastly. It should be noted that the formation order of the display elements DE1, DE2 and DE3 is not limited to this example.

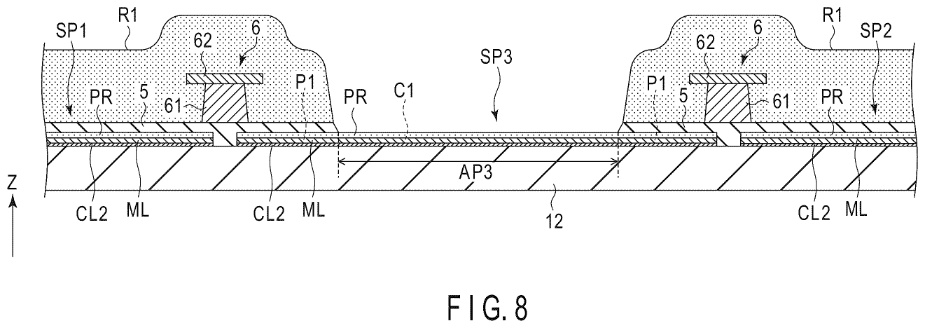

To form the third display element DE3, first, as shown in FIG. 8, a resist R1 which is open in the third subpixel SP3 is formed on the rib 5 and the partition 6. Further, the third pixel aperture AP3 overlapping the protective layer PR of the third subpixel SP3 is formed in the rib 5 by etching using the resist R1 as a mask.

Of the metal layer ML of the third subpixel SP3, the portion which overlaps the third pixel aperture AP3 corresponds to the first central portion C1 shown in FIG. 4, and the remaining portion corresponds to the first peripheral portion P1 shown in FIG. 4. As the third pixel aperture AP3 is formed, of the protective layer PR of the third subpixel SP3, the portion which covers the first central portion C1 of the metal layer ML is exposed from the rib 5. After the formation of the third pixel aperture AP3, the resist R1 is removed by an exfoliation liquid.

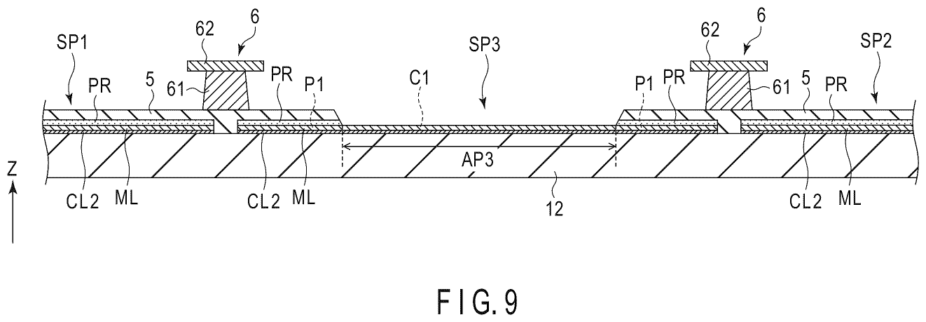

Subsequently, as shown in FIG. 9, of the protective layer PR of the third subpixel SP3, the portion exposed from the rib 5 through the third pixel aperture AP3 is removed by etching. By this process, the first central portion C1 of the metal layer ML is exposed from the protective layer PR. To prevent the metal layer ML from corroding by the etching, the protective layer PR and the metal layer ML should be preferably formed of materials exhibiting a good selective ratio in the etching.

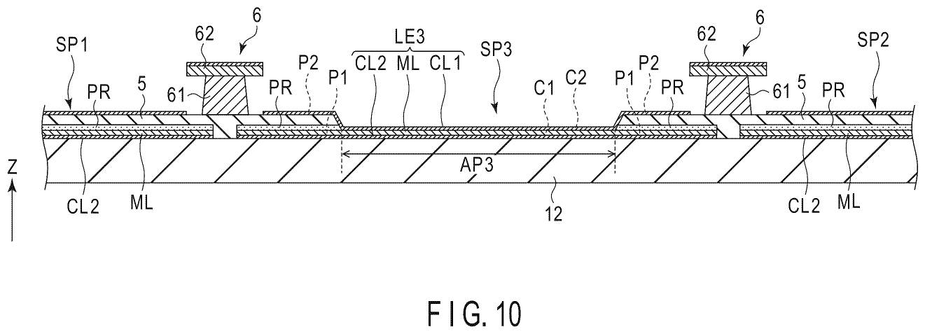

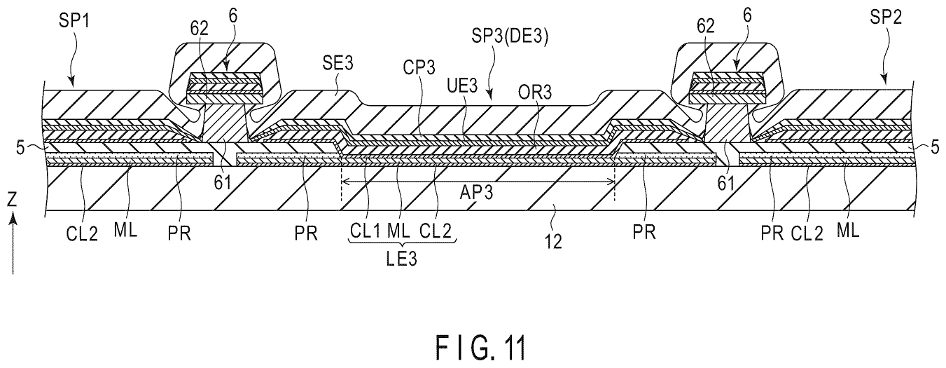

Subsequently, as shown in FIG. 10, the first conductive oxide layer CL1 which is thinner than the protective layer PR is formed on the entire substrate by sputtering. By this process, the third lower electrode LE3 including the metal layer ML, the first conductive oxide layer CL1 and the second conductive oxide layer CL2 is formed in the third subpixel SP3.

Of the first conductive oxide layer CL1, the portion formed in the third subpixel SP3 corresponds to the second central portion C2 shown in FIG. 4 and is in contact with the first central portion C1 of the metal layer ML through the third pixel aperture AP3. The remaining portion of the first conductive oxide layer CL1 corresponds to the second peripheral portion P2 shown in FIG. 4 and is located on the rib 5.

The first conductive oxide layer CL1 is formed in each of subpixels SP1, SP2 and SP3. The first conductive oxide layer CL1 is divided by the partition 6. The first conductive oxide layer CL1 is also attached to the upper side of the upper portion 62.

The sputtering described above should be preferably collimated sputtering having a high straightness. By this configuration, the contact between the first conductive oxide layer CL1 and the lower portion 61 of the partition 6 can be prevented.

Subsequently, the third organic layer OR3, the third upper electrode UE3, the third cap layer CP3 and the third sealing layer SE3 are formed in order by vapor deposition for the entire substrate as shown in FIG. 11. At this time, the third organic layer OR3, the third upper electrode UE3 and the third cap layer CP3 formed in subpixels SP1, SP2 and SP3 are divided by the partition 6 having an overhang shape. The third sealing layer SE3 continuously covers the third display element DE3 including the third lower electrode LE3, the third organic layer OR3, the third upper electrode UE3 and the third cap layer CP3 and the partition 6.

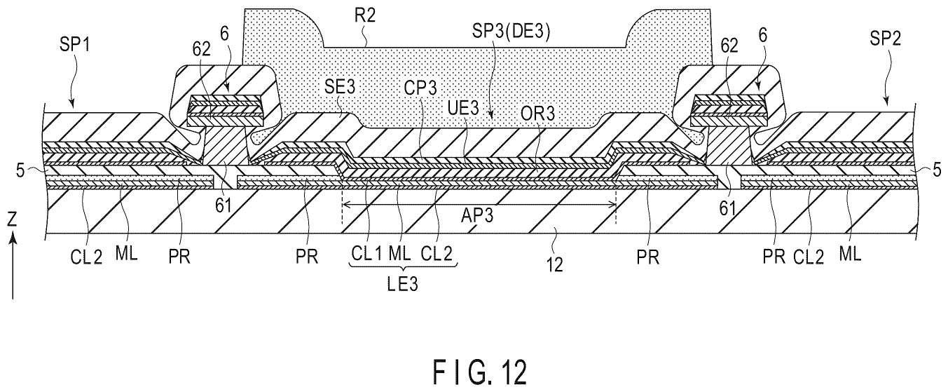

Further, as shown in FIG. 12, a resist R2 is provided on the third sealing layer SE3. The resist R2 has been patterned so as to overlap the third subpixel SP3. The resist R2 is also located immediately above, of the partition 6 surrounding the third subpixel SP3, a portion which is close to the third subpixel SP3.

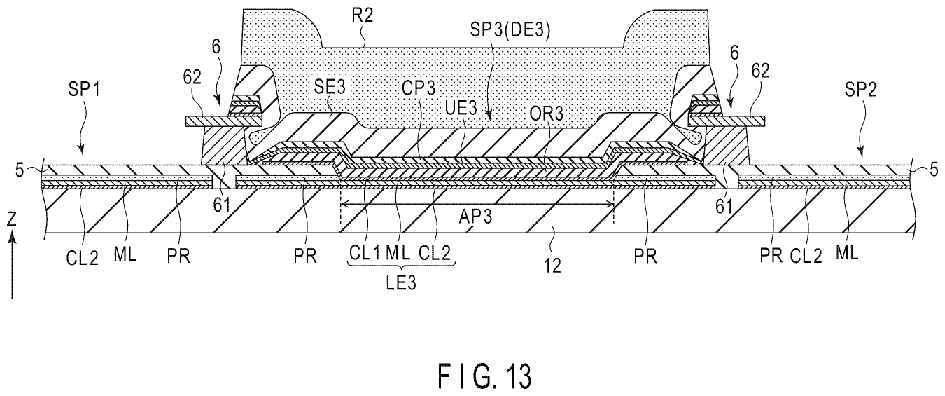

Of the first conductive oxide layer CL1, the third organic layer OR3, the third upper electrode UE3, the third cap layer CP3 and the third sealing layer SE3, the portions exposed from the resist R2 are removed as shown in FIG. 13 by etching using the resist R2 as a mask. This process enables the acquisition of the following substrate. In the third subpixel SP3, the third display element DE3 including the third lower electrode LE3, the third organic layer OR3, the third upper electrode UE3 and the third cap layer CP3 is formed, and the third sealing layer SE3 which covers the third display element DE3 is also formed. No display element or sealing layer is formed in subpixel SP1 or SP2.

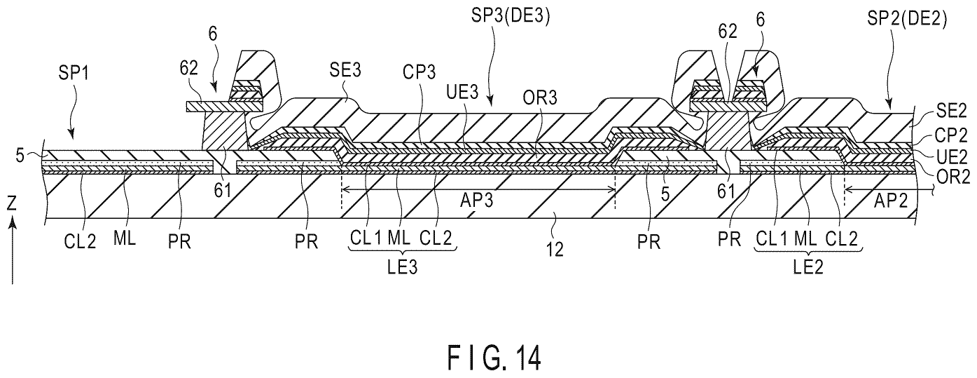

Subsequently, the resist R2 is removed, and a process for forming the second display element DE2 in the second subpixel SP2 is performed by a procedure similar to that of FIG. 8 to FIG. 13. This process enables the formation of, as shown in FIG. 14, the second pixel aperture AP2, the first conductive oxide layer CL1 which is in contact with the metal layer ML through the second pixel aperture AP2, the second organic layer OR2 which covers the first conductive oxide layer CL1, the second upper electrode UE2 which covers the second organic layer OR2, the second cap layer CP2 which covers the second upper electrode UE2 and the second sealing layer SE2 which covers the second cap layer CP2.

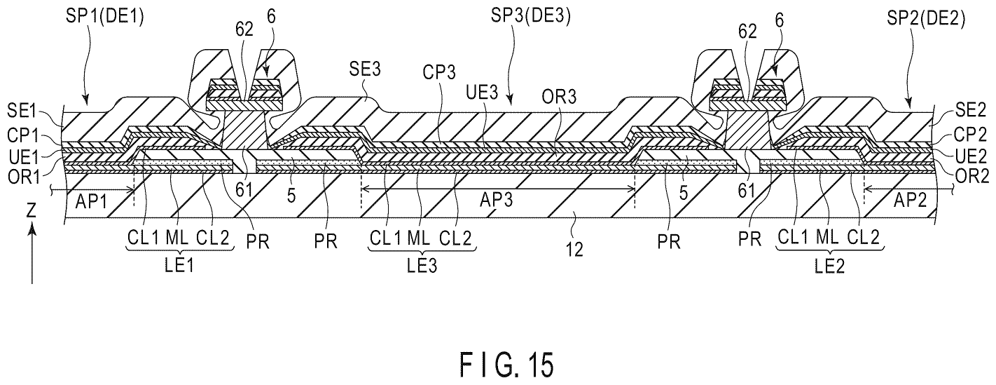

After the formation of the second display element DE2, a process for forming the first display element DE1 in the first subpixel SP1 is performed by a procedure similar to that of FIG. 8 to FIG. 13. This process enables the formation of, as shown in FIG. 15, the first pixel aperture AP1, the first conductive oxide layer CL1 which is in contact with the metal layer ML through the first pixel aperture AP1, the first organic layer OR1 which covers the first conductive oxide layer CL1, the first upper electrode UE1 which covers the first organic layer OR1, the first cap layer CP1 which covers the first upper electrode UE1 and the first sealing layer SE1 which covers the first cap layer CP1.

After the formation of the display elements DE1, DE2 and DE3 and the sealing layers SE1, SE2 and SE3, the processes of forming the resin layer 13, the sealing layer 14 and the resin layer 15 are performed in series. In this way, the display device DSP comprising the structure shown in FIG. 3 is completed.

The anode of an organic EL display device may comprise a structure in which a conductive oxide layer is stacked on a metal layer in a manner similar to that of the lower electrodes LE1, LE2 and LE3 of the present embodiment. The metal layer formed of, for example, silver, easily corrodes by the exfoliation liquid used to remove the resist for forming a pixel aperture in a rib or remove a residue. If the conductive oxide layer is thin, the exfoliation liquid could reach the metal layer through a pin hole which could be formed in the conductive oxide layer. If the metal layer is covered with a conductive oxide layer having a sufficient thickness, the metal layer can be protected from corrosion by the exfoliation liquid. However, if the conductive oxide layer is too thick, the optical property of the display element is impaired.

In the present embodiment, when the pixel apertures AP1, AP2 and AP3 are formed in the rib 5, the metal layers ML overlapping the pixel apertures are covered with the protective layers PR. By forming the protective layers PR so as to have a sufficient thickness or forming the protective layers PR by a material which is not easily impregnated with an exfoliation liquid for removing the resist R1, the metal layers ML can be protected from the exfoliation liquid, etc.

Further, when the display elements DE1, DE2 and DE3 are formed, the protective layers PR are partly removed, and the first conductive oxide layers CL1 which are in contact with the metal layers ML are formed. Since the first conductive oxide layers CL1 are not exposed to an exfoliation liquid, the first conductive oxide layers CL1 can be made thin so as to exhibit a good optical property.

In this way, according to the display device DSP of the present embodiment and the manufacturing method thereof, the reliability of the display device DSP can be improved, and further, the display quality can be improved.

In the display device DSP of the present embodiment, the first conductive oxide layers CL1 are also located on the rib 5. By this configuration, the facing areas of the lower electrodes LE1, LE2 and LE3 and the upper electrodes UE1, UE2 and UE3 are made greater than the areas of the pixel apertures AP1, AP2 and AP3. As a result, the light emitting areas of the organic layers OR1, OR2 and OR3 are also widened, thereby increasing the luminance of subpixels SP1, SP2 and SP3.

In the present embodiment described above, this specification assumes a case where the third pixel aperture AP3 is formed after the formation of the partition 6, and the second pixel aperture AP2 is formed after the formation of the third display element DE3, and the first pixel aperture AP1 is formed after the formation of the second display element DE2. As another example, the pixel apertures AP1, AP2 and AP3 may be formed at the same time before the formation of the partition 6. As yet another example, after the formation of the partition 6, the pixel apertures AP1, AP2 and AP3 may be formed at the same time before the formation of the third display element DE3. Even in these cases, as long as the metal layers ML are covered with the protective layers PR when the pixel apertures AP1, AP2 and AP3 are formed, the metal layers ML can be protected from, for example, the exfoliation liquid which is subsequently used.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a lower electrode;
a rib which covers a part of the lower electrode and comprises a pixel aperture overlapping the lower electrode;
an upper electrode which faces the lower electrode; and
an organic layer which is provided between the lower electrode and the upper electrode and emits light based on a potential difference between the lower electrode and the upper electrode, wherein
the lower electrode includes:
a metal layer comprising a first peripheral portion covered with the rib, and a first central portion exposed from the rib through the pixel aperture; and
a conductive oxide layer comprising a second peripheral portion located on the rib, and a second central portion which is in contact with the first central portion through the pixel aperture.

2. The display device of claim 1, further comprising a protective layer which covers the first peripheral portion.

3. The display device of claim 2, wherein
the rib covers the protective layer.

4. The display device of claim 2, wherein
the protective layer is thicker than the conductive oxide layer.

5. The display device of claim 2, wherein
the protective layer surrounds the first central portion.

6. The display device of claim 2, wherein
the protective layer is conductive.

7. The display device of claim 6, wherein
the conductive oxide layer and the protective layer are formed of ITO, IZO or IGZO.

8. The display device of claim 1, further comprising a conductive partition provided on the rib, wherein
the upper electrode is in contact with the partition.

9. The display device of claim 8, wherein
the partition comprises a conductive lower portion, and an upper portion which protrudes from a side surface of the lower portion.

10. The display device of claim 9, wherein
the conductive oxide layer is partly located on the upper portion.

11. A display device comprising:
a lower electrode;
a rib which covers a part of the lower electrode and comprises a pixel aperture overlapping the lower electrode;
an upper electrode which faces the lower electrode;
an organic layer which is provided between the lower electrode and the upper electrode and emits light based on a potential difference between the lower electrode and the upper electrode; and
a protective layer located between the lower electrode and the rib, wherein
the lower electrode includes:
a metal layer comprising a first peripheral portion covered with the rib, and a first central portion exposed from the rib through the pixel aperture; and
a conductive oxide layer which covers the first central portion, and
the protective layer covers the first peripheral portion.

12. The display device of claim 11, wherein
the protective layer is thicker than the conductive oxide layer.

13. The display device of claim 11, wherein
the protective layer surrounds the first central portion.

14. A manufacturing method of a display device, including:
forming a metal layer;
forming a protective layer which covers the metal layer;
forming a rib which covers a part of the protective layer and comprises a pixel aperture overlapping the protective layer;
removing, of the protective layer, a portion exposed from the rib through the pixel aperture such that a first central portion of the metal layer is exposed from the protective layer;
forming a conductive oxide layer which is in contact with the first central portion through the pixel aperture;
forming an organic layer which covers the conductive oxide layer; and
forming an upper electrode which covers the organic layer.

15. The manufacturing method of claim 14, wherein
the conductive oxide layer is formed so as to be thinner than the protective layer.

16. The manufacturing method of claim 14, further including
forming a partition on the rib before the first central portion of the metal layer is exposed from the protective layer, the partition comprising a conductive lower portion and an upper portion protruding from a side surface of the lower portion.
